(19) United States
(12) Patent Application Publication
(10) Pub. No.: US 2026/0002251 A1
(43) Pub. Date: Jan. 1, 2026

(54) CONDUCTIVE SPUTTERING TARGET AND METHOD FOR DEPOSITING A LAYER THEREWITH

(71) Applicant: SOLERAS ADVANCED COATINGS BV, Deinze (BE)

(72) Inventors: Ignacio CARETTI GIANGASPRO, Madrid (ES); David DEBRUYNE, Gent (BE); Freddy FACK, Mariakerke (BE); Wilmert DE BOSSCHER, Drongen (BE)

(21) Appl. No.: 19/109,345

(22) PCT Filed: Sep. 1, 2023
(86) PCT No.: PCT/EP2023/073984

§ 371 Date: Mar. 6, 2025

(30) Foreign Application Priority Data
Sep. 9, 2022 (BE) 2022/5713

(51) Int. Cl. C23C 14/34; C23C 14/06

(52) U.S. Cl. CPC C23C 14/3414; C23C 14/0676

(57) ABSTRACT

A target for sputtering in mid-frequency AC sputtering processes, or DC sputtering processes includes a target material layer mainly including M-doped LixPOy, wherein x is from 2.5 to 3.5 and wherein y is from 2.5 to 4.5, wherein M represents up to 40 wt. % of the target material layer, and wherein M is least one chemical element from groups 13 to 15 of the periodic table, wherein M is selected for providing electrical conductivity to the target material layer such that an electrical resistivity of the target material layer is at most 1000 Ω·cm at room temperature, and wherein the target material layer has a lamellar structure consisting of microscopic splats of material.

### TECHNICAL FIELD OF THE INVENTION

The present invention relates to the field of sputtering targets. More specifically, the present invention relates to a conductive sputtering target that may be used for depositing a LiPON layer, to a method for forming said conductive sputtering target, and to a method of sputtering the conductive sputtering target.

### BACKGROUND OF THE INVENTION

The technique of material deposition by means of sputtering is known already for many decades. Typically, a plasma is generated in a low pressure chamber in which an inert gas such as argon, and/or a reactive gas such as oxygen or nitrogen is present, and a negative voltage is applied on a so called “sputter target”, i.e., a target for sputtering (containing the material to be deposited), with the intention of depositing a layer of the sputter material onto a “substrate”. The gas atoms can be ionized, and the sputter target is bombarded by the gas ions, so that atoms are freed from the sputter target, and move to the substrate, where they are deposited.

In such sputtering process, typically three kinds of power sources are being used: DC power, AC or pulsed power (in the range of kHz, e.g. at a frequency of 1 to 100 kHz) and RF power (in the range of MHz, e.g. at a frequency of 0.3 to 100 MHz). DC power is typically used when the deposited material forms a substantially electrical conductive layer. AC power is typically used when the deposited layer has lower conductivity or is dielectric. Although high frequency power (RF power) enables the sputtering of material with low conductivity, uniform deposition on a larger substrate area is challenging, due to standing wave effects. Moreover, the sputter rate for same power levels is typically significantly lower compared to a DC process. Furthermore, the application of RF power is not simple (due to, a.o., issues related to impedance matching, shielding, . . . ), and RF sputtering requires very expensive power supplies (price/kW) while providing only limited maximum powers. Furthermore, it is difficult to apply such an RF field uniformly across targets having a large size (e.g., having dimensions exceeding 0.5 m, or even 1 m or larger), which are preferably used in commercial manufacturing, for coating substrates that have a large surface area. Some types of layers are thus more difficult to obtain especially uniformly across larger substrates.

The dielectric material LiPON has received continued attention, in particular for its use as electrolyte material. The main reasons for this are: its wide stability window, that is from 0 to 5V vs Li⁺/Li; its reasonable ionic conductivity (˜10⁻⁶ S/cm); and its low electronic conductivity (electronic resistivity of ˜10¹⁴ Ω·cm). At present, LiPON is used in commercial thin-film batteries, as the most frequently used solid electrolyte in the thin-film battery community. One technique for forming LiPON layers is through deposition of LiPON material by sputtering.

LiPON may be deposited by sputtering from a Li₃PO₄ target. Indeed, when Li₃PO₄ is sputtered in a reactive gas atmosphere comprising nitrogen so that nitrogen plasma is formed while sputtering, nitrogen is incorporated into the layer, leading to the formation of LiPON. As Li₃PO₄ targets are dielectric, that is, electrically non-conductive, typically, a radio frequent (RF) alternating field has to be used for sustaining long term stable sputtering. Therefore, sputtering of LiPON from a Li₃PO₄ target may have any of the problems relating to RF sputtering as outlined above.

Several prior art documents describe possible solutions to these problems. U.S. Pat. No. 11,081,325B2 discloses a conductive target, which comprises regions formed of Li₃PO₄ and separate regions formed of carbon. Furthermore, the target comprises percolating regions of Li₂CO₃, which may improve the conductivity of the target. Carbon in the target may, during sputtering, react with oxygen in the sputtering atmosphere to form CO and CO₂, which may be pumped out of the system, so that no carbon is incorporated in the deposited layer.

WO2015158607A1 discloses a target comprising LiPON for forming a solid electrolyte layer comprising LiPON. The target is made conductive by the presence of a material with electrical conductivity, such as carbon, polymers, and salts, e.g., lithium or ammonium salts. The material with electrical conductivity may be converted to an inert material during sputtering, and may either not be present in the deposited solid electrolyte layer, or is only incorporated therein in a small amount or in a modified form. As a result, the layer properties of the solid electrolyte layer are not negatively influenced. In particular, carbon may react with oxygen in the reaction chamber, thereby forming CO and CO₂. Decomposition products of, e.g., conductive polymers used as the material with electrical conductivity may be incorporated in the deposited solid electrolyte layer. When the material is a salt, the constituents of the corresponding ions forming the salt are, likewise, deposited on the solid electrolyte layer or remain in the gas phase.

WO2007042394A1 describes a target, which may be formed of LiPON, that is made conductive by the addition of a doping element. The doping element, or a reaction product thereof (e.g., by reaction with the sputter gas), may be sublimated or evaporated during the sputter process. Due to said sublimation or evaporation of the doping element, the deposited coating, e.g., LiPON, does not comprise the doping element. Some of the preferred doping elements are tin, bismuth and antimony. In particular, tin may form an oxide with a low evaporation/sublimation temperature. The target may be heated to a temperature above a temperature of the atmosphere in the sputtering chamber, so as to prevent deposition of the oxidized doping material in the deposited coating.

There is, however, still room in the art for alternative devices and methods that address at least some of the above problems.

### SUMMARY OF THE INVENTION

It is an object of the present invention to provide a good target for providing a layer predominantly comprising LiPON on a substrate by sputtering. It is a further object of the present invention to provide a good method for depositing a layer using said target for sputtering.

The above objective is accomplished by a device and method according to embodiments of the present invention.

It is an advantage of embodiments of the present invention that a material is present in the target material layer to render it electrically conductive, and that said material reacts during deposition by sputtering to form an insulating layer. As a result, the target may be electrically conductive, while the deposited layer may be electrically insulating.

It is an advantage of embodiments of the present invention that the target can be used in mid-frequency AC sputtering processes, or in DC sputtering processes, for instance in pulsed-DC sputtering processes. The frequency of the periodic change of the electrical signal used in these sputtering processes may be between 0 Hz (DC) and up to 250 kHz, but more typically between 20 kHz and 100 kHz.

It is a further advantage of embodiments of the present invention that the target material has a lamellar structure consisting of microscopic splats. As a result, the target may have a continuous and large single surface area, and may have a large thickness and hence material inventory, which may enable depositing large area coatings without having to frequently replace the target, limiting down-time of a sputtering system using the target of the present invention.

It is an advantage of embodiments of the present invention that the formation of electrically highly resistive deposited layers comprising LiPON, such as electrolyte layers, may be facilitated. An electrolyte layer acts as a conductor for ions, but has a high resistivity for electrical conduction (driven by electrons).

In a first aspect, the present invention relates to a target that may be used for sputtering in mid-frequency AC sputtering processes, or DC sputtering processes, wherein the DC sputtering processes may be pulsed or non-pulsed DC sputtering processes. The target comprises a target material layer mainly comprising M-doped LiₓPO_{y}, namely at least 50 wt. %, for instance at least 60 wt. %, or even much more, such as at least 80 wt. %, at least 90 wt. %, at least 95 wt. %, at least 97 wt % of the weight of the target material layer. Herein, x is from 2.5 to 3.5 and y is from 2.5 to 4.5, and M represents up to 40 wt. %, e.g., up to 30 wt. %, for instance up to 25 wt %, such as up to 20 wt. %, of the target material layer. In particular embodiments, M represents at least 1 wt. %, for instance at least 5 wt. %, such as e.g. at least 10 wt. %, of the target material layer. M comprises at least one chemical element from groups 13 to 15 of the periodic table (in accordance with the IUPAC numbering of groups), and is selected for providing electrical conductivity to the target material layer such that an electrical resistivity of the target material layer is at most 1000 Ω·cm at room temperature, i.e., 20° C. The M addition is preferably not oxidized or nitridized because its main goal is for providing conductivity on target level. Moreover, LiₓPO_{y} may be substoichiometric, which may contribute to further improve the electrical conductivity of the target. The target material layer has a lamellar structure, such as the one typically produced by spraying, consisting of microscopic splats of material.

It is an advantage of embodiments of the present Invention that the splat-like structure results in a reduced stress in the target, so that the target may be thick without risking the target to break during sputtering.

The target material layer being formed of splats of material may result in pores being present in the target material layer. The target material layer may have a porosity (defined as volume of pores in the target material layer per volume of the target material layer) of at least 0.1%, preferably at least 0.5%, more preferably at least 1%. The target material layer may have a porosity below 20%, preferably below 10% and more preferably a porosity of 5% or less. The pores may be beneficial in terms of reducing internal stress and mechanical failure during target manufacturing or sputter deposition.

In embodiments, the target material layer comprises at least 80 wt. %, e.g., at least 90 wt. %, such as at least 95 wt. %, for example, at least 97 wt. %, of M-doped LiₓPO_{y}.

In embodiments, M represents from 0.01 wt. % to 40 wt. %, for instance from 1 wt. % to 40 wt. %, such as from 5 to 25 wt. %, of the total weight of the target material layer, e.g. from 10 to 20 wt. % of the total weight of the target material layer. In embodiments, M represents from 0.01 wt. % to 40 wt. %, for instance from 1 wt. % to 40 wt. %, such as from 5 to 25 wt. %, of the total weight of the M-doped LiₓPO_{y} fraction of the target material layer.

In embodiments, M being selected for providing electrical conductivity to the target material layer at least means that M is present in the target in an electrically conductive form. For example, preferably, the dopant M is in an unoxidized or non-nitrided state, in particular when M is a metal or metalloid. For example, when M is a metal, it is preferably present in the target material layer in a metallic state. Furthermore, while, e.g., elemental nitrogen is typically electrically insulating (and therefore, as such, excluded as being the at least one chemical element of M), M may be an electrically conductive compound comprising nitrogen. In turn, M may also be an electrically conductive compound containing oxygen. In embodiments, M may comprise any material configured for providing the electrical conductivity to the target material layer, and formed of at least one chemical element from group 13 to 15 of the periodic table, which may include, e.g.: conductive carbon compounds, such as graphene; electrically conductive polymers; or metals and/or metalloids.

In embodiments, M comprises, or consists of, at least one chemical element from period 2 to 4 of the periodic table. In embodiments, M comprises, or consists of, at least one chemical element selected from boron, aluminium, gallium, silicon, germanium, nitrogen, phosphorus, and arsenic. In particular embodiments, M comprises, or consists of, at least one metal and/or a metalloid element. The following elements are understood to be metalloid elements: boron, silicon, germanium, arsenic, antimony, and tellurium. In embodiments, M is a metal and/or a metalloid. In embodiments, M comprises, or consists of, at least one chemical element from group 13 of the periodic table. In embodiments, M comprises, or consists of, at least one chemical element selected from silicon, boron, aluminium, and gallium. In particular embodiments, M is aluminium. It is an advantage of these embodiments that metals and metalloids are typically highly electrically conductive. It is a further advantage of these embodiments that metals and metalloids may react during sputtering, with a reactive gas such as nitrogen or oxygen, to form a nitride or oxide that is typically electrically insulating. This material may then be deposited in or with the deposited layer, together with LiPON formed from the LiₓPO_{y} after reaction with nitrogen, without substantially negatively affecting the electrically insulating properties of the LiPON. In other words: notwithstanding the presence of the nitride or the oxide of the metal or metalloid, the deposited LiPON layer may be electrically insulating. As the nitride or oxide of M may be deposited together with the LiPON in the deposited layer, no complicated techniques are required for preventing M from being deposited in the deposited layer. In embodiments, M is a material having an electrical resistivity of at most 1000 Ω·cm, preferably at most 10 Ω·cm, more preferably at most 0.1 Ω·cm.

In embodiments, the target is a cylindrical target. Cylindrical targets may facilitate uniform use of target material, e.g., when rotating the cylindrical target during sputtering. The invention is, however, not limited to any shape of the target, and instead, the target may, for example, be planar, e.g., typically rectangular or circular, or be prismatic.

In particular embodiments, the microscopic splats comprise first regions of M and second regions of LiₓPO_{y}. In other words, in the target material layer, there may be substantially no mixing of M and LiₓPO_{y}. In embodiments, the microscopic splats may comprise first microscopic splats formed of M, and second microscopic splats formed of LiₓPO_{y}. In alternative embodiments, individual microscopic splats may comprise first regions of M and second regions of LiₓPO_{y}.

In embodiments, M being selected for providing electrical conductivity to the target material layer means that the structure of the target material layer is such that there are electrical conduction paths percolating through the target material layer. In other words, preferably, non-intermitted paths of M (that is, not intermitted by LiₓPO_{y}, or, when present, another electrically insulating material), are present in the target material layer. In order to achieve this, the first regions of M of neighboring splats may be in electrical contact with each other for at least part of the splats. It is an advantage of these embodiments of the present invention that the conductivity of the target material layer may be substantially defined by the conductivity of M. It is an advantage of these embodiments that a front surface of the target material layer, from which target material may be sputtered, may be electrically coupled with a back surface of the target material layer, which may contact a backing substrate to which an AC or DC sputtering voltage may be applied. However, the invention is not limited to non-intermitted paths of M: for example, regions formed of non-M material (e.g., LiₓPO_{y}) between intermitted regions formed of M may be sufficiently thin so as to not considerably inhibit electrical conduction throughout the target material layer. Hereto, M may be provided in an amount of at least 1 wt. %, e.g. at least 5 wt. %, preferably higher than 10 wt. % of the total weight of the target material layer. Furthermore, electronic conductivity through the regions formed of non-M material (e.g., LiₓPO_{y}) may be possible by the presence of defects, and also electronic conduction along grain boundaries may be possible.

The electrical resistivity may be the electrical resistivity between two different locations, e.g., between the front and back surface, of the target material layer, through the target material layer. Said electrical resistivity may be determined by any method as is known to the person skilled in the art.

In some embodiments, the target consists of the target material layer. Preferably, however, the target further comprises a backing substrate, e.g., a backing plate (although the backing substrate is not limited to any shape), in electrical contact with the target material layer. In embodiments, the target material layer is bonded to the backing substrate by means of a specific interface morphology and/or an electrically conductive bonding layer. For example, the bonding layer may comprise a metal, a metal compound, a metal-doped epoxy or a metal-doped elastomer, the invention not being limited thereto. The interface morphology may comprise, or consist of, a specific roughness for favouring mechanical interlocking the target material layer onto the backing structure.

In the present invention, the target material layer has a lamellar structure. A lamellar structure comprises fine, distinguishable layers (at microscopic level), called lamellae. In the present invention, the lamellae are formed by splats of raw material that have been projected onto a backing substrate of the target, for instance in molten, semi-molten or non-molten form. The lamellae are formed upon impact of the raw material onto the backing substrate. In embodiments of the present invention, the lamellae may be layers with a thickness of from 0.1 μm to 10 μm. The different lamellae may have different degrees of crystallinity, different densities, etc. The lamellae may be formed by microscopic splats of material, having an average volume of, e.g., from 0.00001 to 0.001 mm³, such as 0.0001 mm³, depending on the target manufacturing conditions (e.g., powder of sprayed particles). The composition of the lamellae depends on the raw materials that have been projected. In embodiments of the present invention, the lamellar structure is due to a spraying process, for instance—but not limited thereto—a thermal spraying process.

In a second aspect, the present invention relates to a method for forming a target for sputtering. The target thus formed may be used for sputtering in mid-frequency AC sputtering processes or DC sputtering processes. The method comprises providing powder comprising: particles of lithium phosphate and particles of M; and/or particles of M-doped lithium phosphate. Herein, M comprises at least one chemical element from groups 13 to 15 of the periodic table. The method further comprises providing a backing substrate. The method further comprises spraying splats, formed upon impact of the powder, onto the backing substrate, so as to form a target material layer comprising M-doped LiₓPO_{y}, wherein x is from 2.5 to 3.5 and wherein y is from 2.5 to 4.5, wherein M represents up to 40 wt. % of the total target material, and wherein M is selected for providing electrical conductivity to the target material layer such that an electrical resistivity of the target material layer is at most 1000 Ω·cm at room temperature, i.e., 20° C. It is an advantage of using spraying to form the target for sputtering, that the target material layer may have a structure consisting of splats of said target material. Such a splat-like structure may have the advantage that stress may be mitigated in the target material layer, so that large targets may be formed.

Typically, the powder has, i.e., the particles have, on average, a composition suitable for forming said M-doped LiₓPO_{y}. In general, the powder and the target material layer formed of the powder typically have substantially the same composition. However, this does not necessarily mean that each particle is formed of at least one of M-doped LiₓPO_{y}, LiₓPO_{y} or M. Indeed, some particles may have a composition that differs therefrom: for example, although at least some of said (e.g., M-doped) lithium phosphate particles may be formed of (e.g., M-doped) LiₓPO_{y}, at least some other (e.g., M-doped) lithium phosphate particles may be formed of (e.g., M-doped) Li₄P₂O₇ or Li₃PO₄. In embodiments, particles of M-doped lithium phosphate may comprise lithium phosphate with M on their surface, e.g., coated with M.

In particular embodiments wherein the powder comprises the particles of lithium phosphate and the particles of M, the particles of M may represent up to 40 wt. %, e.g., up to 30 wt. %, such as up to 20 wt. %, of the powder. In these particular embodiments, the particles of M may represent at least 1 wt. %, for instance at least 5 wt. %, such as at least 10 wt. %, of the powder.

In embodiments, providing a backing substrate comprises providing a backing substrate comprising a specific interface morphology and/or a bonding layer. In alternative embodiments, the steps of providing a backing structure, and providing a specific interface morphology and/or the bonding layer on the backing structure, may be two separate steps. The specific interface morphology and/or the bonding layer may be configured for fixing the splats to the backing substrate during said spraying of powder onto the backing substrate.

In embodiments, said spraying is thermal spraying. In embodiments, said spraying comprises melting the particles, or at least partially melting the particles, which may comprise heating the particles to a temperature that is at least the melting temperature of the particles, e.g., that is at least the melting temperature of M and/or at least the melting temperature of the lithium phosphate. In a thermal spray process, superheated molten or semi-molten particles are projected at high velocities onto the proportionally much colder carrier material and solidify rapidly in a typical splat-like microstructure to form a coating of a desired thickness. Controlling the production temperature and microstructure of the thermally sprayed target material layer allows minimizing its internal stresses and, hence, the risk of target failure during sputtering by cracking or spallation, especially in the case of ceramic materials. However, instead, also other spraying techniques, such as cold spraying, may be used.

In some embodiments, the surface of the target material layer can be polished to reduce its roughness and possible subsequent problems during sputtering, such as arcing.

In a third aspect, the present invention relates to a method for depositing a layer on a substrate. The method comprises obtaining a target in accordance with embodiments of the first aspect of the present invention. The method further comprises sputtering, in a reactive gas atmosphere at least comprising N₂, target material from the target material layer of the target onto the substrate. Said sputtering is performed such that M reacts with a component of the reactive gas atmosphere, thereby forming an electrically insulating material, so as to form the deposited layer comprising LiPON and said electrically insulating material. It is an advantage of embodiments of the present invention that M that provides electrical conductivity to the target, may be transformed, during the sputtering, into an insulating material and be deposited in the deposited layer, together with the LiPON formed from a reaction of LiₓPO_{y} with the N₂. In embodiments, the relative amounts of Li, P, and M in the deposited layer are substantially the same as the relative amounts of Li, P, and M in the target material layer, although the invention is not limited thereto.

In embodiments, said sputtering is DC sputtering or AC sputtering at a frequency of at most 250 kHz. In embodiments, said DC sputtering processes may be non-pulsed or pulsed DC sputtering, wherein a pulse frequency, i.e., a frequency of periodic change of the electrical signal is from 0 Hz up to 250 kHz, and more typically is from 20 kHz to 100 kHz. It is an advantage of these embodiments that the sputtering process may be efficient.

In embodiments, said sputtering is performed such that M reacts with nitrogen during sputtering to form a nitride of M. Nitrides of chemical element from groups 13 to 15 of the periodic table are often electrically insulating. Examples include: AlN, having an electrical resistivity of over 10¹¹ Ω·cm; BN, having an electrical resistivity of over 10¹⁴ Ω·cm; and Si₃N₄ having an electrical resistivity of over 10¹³ Ω·cm. Although N₂ is preferred for reacting with M, as N₂ is present anyway for reacting with LiₓPO_{y} for forming LiPON, instead, the reactive gas atmosphere may further comprise O₂ for reacting with M. Indeed, also oxides of electrically conductive materials are typically electrically insulating. Therefore, in embodiments, the reactive gas atmosphere further comprises O₂. In embodiments, the reactive gas atmosphere in the sputtering chamber may further comprise an inert gas, such as Ne, Ar, Kr, or Xe, preferably Ar.

In embodiments, the pressure of the atmosphere in the sputtering chamber is typically from 0.1 Pa to 10 Pa. Typically, a controlled flow of reactive gas into the vacuum chamber is used, so as to compensate for any loss of N₂, and possibly O₂, by their reaction with the target material layer. Thereby, the composition of the reactive gas atmosphere may stay the same while sputtering.

In embodiments, said sputtering is performed so as to form a deposited layer having an electrical resistivity that is at least 10⁴ Ω·cm, at least 10⁷ Ω·cm, preferably at least 10⁹ Ω·cm, more preferably at least 10¹¹ Ω·cm, even more preferably at least 10¹³ Ω·cm. In embodiments, the deposited layer may have a thickness ranging from 20 to 2000 nm, preferably from 50 to 1500 nm, more preferably from 100 to 1200 nm.

In embodiments, the substate onto which the layer is deposited comprises silicon, glass, or an electrode material, but the invention is not limited thereto.

In a fourth aspect, the present invention provides use of a target according to any of the embodiments of the first aspect in a stable plasma sputtering process powered by a mid-frequency sputtering process or a DC sputtering process.

Particular and preferred aspects of the invention are set out in the accompanying independent and dependent claims. Features from the dependent claims may be combined with features of the independent claims and with features of other dependent claims as appropriate and not merely as explicitly set out in the claims.

The above and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

### BRIEF DESCRIPTION OF THE DRAWINGS

FIG. 1 is a scheme of a method in accordance with embodiments of the second aspect of the present invention.

FIG. 2 is a schematic representation of a cross-section of a target for sputtering in accordance with embodiments of the present invention.

FIG. 3 is a first exemplary schematic representation of part of a cross-section of a target material layer of a target for sputtering in accordance with embodiments of the present invention.

FIG. 4 is a second exemplary schematic representation of part of a cross-section of a target material layer of a target for sputtering in accordance with embodiments of the present invention.

FIG. 5 is an optical microscopy image of part of a target material layer of a target in accordance with embodiments of the present invention.

FIG. 6 is a scanning electronic microscope image of part of the target material layer of the target of FIG. 5, which is in accordance with embodiments of the present invention.

FIG. 7 is an X-ray diffraction (XRD) spectrum of the first region formed of Al overlayed with an XRD spectrum of the second region formed of LiₓPO_{y}, of a single target material layer of a target in accordance with embodiments of the present invention.

FIG. 8 to FIG. 11 are schematic representations of setups that may be used for measuring the electrical conductivity of a target material layer of a target in accordance with embodiments of the present invention.

FIG. 12 is a schematic representation of a sputtering setup for use in a method for depositing a layer, wherein the method is in accordance with embodiments of the present invention.

In the different figures, the same reference signs refer to the same or analogous elements.

### DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

The terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top and over and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. The term “comprising” therefore covers the situation where only the stated features are present and the situation where these features and one or more other features are present. The word “comprising” according to the invention therefore also includes as one embodiment that no further components are present. Thus, the scope of the expression “a device comprising means A and B” should not be interpreted as being limited to devices consisting only of components A and B. It means that with respect to the present invention, the only relevant components of the device are A and B.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

The following terms are provided solely to aid in the understanding of the invention.

As used herein, and unless otherwise specified, a splat is a microscopic entity obtained by projecting (e.g., spraying) particles (e.g., molten or semi-molten particles) of target material onto a surface (e.g., onto a top surface of a carrier or onto previously formed splats). By layering splats over one another, a target material layer (e.g., a target material coating) is obtained. In embodiments, the splats may comprise (e.g. consist of) amorphous and/or crystalline target material.

As used herein, and unless otherwise specified, a property denoted as a “splat [property]” corresponds to said property evaluated for a splat as such. For example, a splat composition may correspond to a composition within the boundaries of a splat. Within the present invention, such a splat property need not be constant for all splats and may vary from one splat to another.

As used herein, and unless otherwise specified, a property denoted as a “layer [property]” corresponds to said property evaluated beyond the splat boundaries, e.g. within a region of the target material layer (or within the target material layer as a whole). For example, the layer density may correspond to the density within a region of the target material layer, the region comprising an ensemble of splats and voids therebetween. In embodiments, the region of the target material layer may be selected such that it comprises at least 100 splats, preferably at least 500 splats, most preferably at least 2000 splats, up to for example 10000 or 100000 splats. Within the present invention, such a layer property need not be constant across the whole layer and, indeed, one or more layer properties will typically vary across the whole layer (e.g. across the layer width).

As used herein, and unless otherwise specified, the properties of the microstructure of a target material layer include properties related to splat orientation, splat size, splat shape, splat crystallinity, layer crystallinity, layer density, layer porosity, layer structure, layer order, layer stress, etc.

As used herein, and unless otherwise specified, a structure may typically have a first dimension (e.g. a width), a second dimension (e.g. a length) and a third dimension (e.g. a thickness or height). In embodiments, these three dimensions may typically be perpendicular. In embodiments, the layer thickness may be the direction in which the layering of splats is built up, and the layer width and layer length may be perpendicular thereto. In embodiments, the target thickness, target width and target length may respectively be parallel to the layer thickness, layer width and layer length, respectively. In particular embodiments, the layer width may be equal to or shorter than the layer length. Likewise, the target width may be equal to or shorter than the target length. Of course, the latter does not hold for cylindrical targets.

As used herein, and unless otherwise specified, a backing structure is a carrier for a target material layer, which is adapted for use in a method for manufacturing a sputtering target. In embodiments of the present invention, the backing structure can be pre-shaped in order to compensate for different layer thickness of applied target material at different locations over the width of the target material layer.

Where in embodiments of the present invention reference is made to a composition of M-doped LiₓPO_{y}, reference is made to a composition comprising LiₓPO_{y}, i.e., lithium phosphate wherein the lithium functions as counterion to the phosphate, and M; said LiₓPO_{y} comprising P, x atoms of Li per atom of P, and y atoms of O per atom of P. In embodiments, LiₓPO_{y} and M are separately confined in separate, contiguous, regions.

In the context of the present invention, any electrical conductivity or electrical resistivity that is mentioned is understood to be that defined at room temperature, i.e., 20° C., and at a pressure of 1 atm.

The invention will now be described by a detailed description of several embodiments of the invention. It is clear that other embodiments of the invention can be configured according to the knowledge of persons skilled in the art without departing from the technical teaching of the invention, the invention being limited only by the terms of the appended claims.

In a first aspect, the present invention relates to a target for sputtering in mid-frequency AC sputtering processes, or DC sputtering processes. These sputtering processes may be non-pulsed or pulsed DC sputtering processes or AC sputtering processes, wherein a pulse frequency, i.e., a frequency of periodic change of the electrical signal is from 0 Hz (DC) up to 250 kHz, and more typically is from 20 kHz to 100 kHz.

The target comprises a target material layer mainly comprising M-doped LiₓPO_{y}. Herein, x is from 2.5 to 3.5 and y is from 2.5 to 4.5, and M represents up to 40 wt. % of the target material layer. M comprises at least one chemical element from groups 13 to 15 of the periodic table, and is selected for providing electrical conductivity to the target material layer such that an electrical resistivity of the target material layer is at most 1000 Ω·cm at room temperature. The target material layer has a lamellar structure consisting of microscopic splats of material.

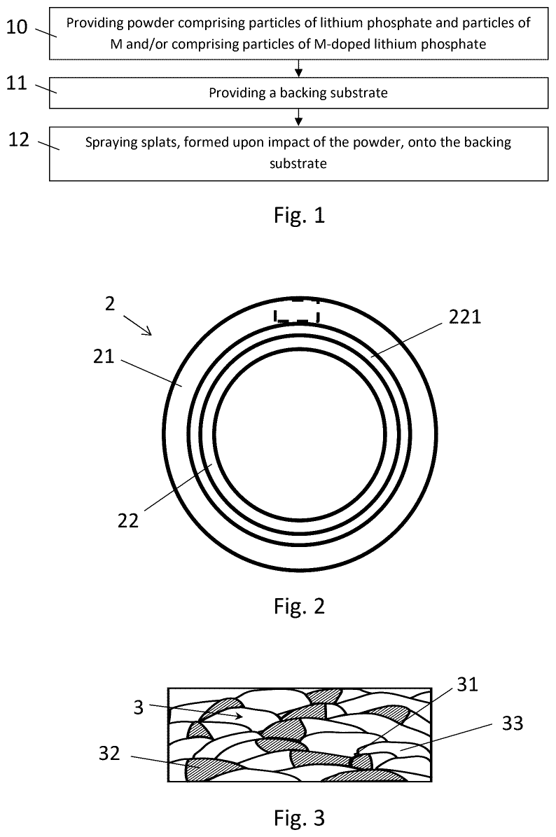

Reference is made to FIG. 1, which is a scheme of a method for forming a target for sputtering in mid-frequency AC sputtering processes or DC sputtering processes, in accordance with embodiments of the second aspect of the present invention.

The method comprises providing 10 a powder comprising: particles of lithium phosphate and particles of M; and/or particles of M-doped lithium phosphate. Herein, M comprises at least one chemical element from groups 13 to 15 of the periodic table. The method further comprises providing 11 a backing substrate. The method further comprises spraying 12 splats, formed upon impact of the provided powder, onto the backing substrate, so as to form a target material layer comprising M-doped LiₓPO_{y}, wherein x is from 2.5 to 3.5 and wherein y is from 2.5 to 4.5, wherein M represents up to 40 wt. % of the total target material, and wherein M is selected for providing electrical conductivity to the target material layer such that an electrical resistivity of the target material layer is at most 1000 Ω·cm at room temperature.

The powder particles are typically in the size range from 10 to 200 microns and flow freely, which allows these powders to be fed consistently into a spray apparatus while being carried by a gas, typically argon, through the feeding hoses and injectors to the apparatus. The thermal spray process consists in accelerating and projecting droplets of source materials (comprising lithium phosphate, M, and/or M-doped lithium phosphate) onto the sputtering backing substrate, where they flatten upon impact to form a coating. In embodiments of the present invention, different types of spraying may be applied, for instance thermal spraying (in which droplets of at least partially molten source materials are projected towards the backing substrate, where they solidify), such as flame spraying, plasma spraying or HVOF, but also cold spraying (if particles are plastically deformable) may be applied.

The environment of the spraying process can be controlled during the target production, which allows controlling the degree of oxidation and of reduction of the powder as raw base material.

FIG. 2 is a schematic representation of a cross-section of an exemplary target 2 for sputtering, wherein the target is in accordance with embodiments of the present invention. In this example, the target 2 is a cylindrical target. The target 2 may be manufactured in accordance with the method as illustrated in FIG. 1. The target 2 comprises a backing substrate 22, which, in this example, has a cylindrical shape. The invention, however, is not limited thereto, and in other embodiments the backing substrate could be flat. The backing substrate 22 is typically formed of an electrically conductive material, such as (stainless) steel, copper or titanium. The backing substrate 22 comprises an interface morphology and/or a bonding layer 221 for promoting adhesion of the target material layer 21 to the backing substrate 22. The interface morphology or the bonding layer 221 may be formed of any material used for bonding of target material layers 221 to backing substrates 22 as known to the skilled person, but is preferably formed of an electrically conductive material, e.g., having an electrical resistivity of at most 1000 Ω·cm, e.g., at most 100 Ω·cm.

A first example of a sub-section of the target material layer 21 within the dashed lines in FIG. 2 is schematically shown enlarged, and in more detail, in FIG. 3. The target material layer is formed of a lamellar structure consisting of microscopic splats 3 of material. The splats 3 are the result of the spraying method, for instance a thermal spraying method, used for forming the target material layer 21, wherein powder particles that are projected towards the backing substrate are deformed upon impacting of the powder particles onto the backing substrate, e.g. at least partially molten, to form splats 3 so as to form the target material layer. These splats 3 are, in the target material layer, in physical contact with each other. Pores 31 may be present in the target material layer, e.g., between adjacent splats 3. These pores 31 may have been introduced during the spraying method used for forming the target material layer.

In this first example, individual splats 3 comprise first regions 32 formed of M and second regions 33 formed of LiₓPO_{y}. It may be observed that at least some of the, electrically conducting, first regions 32 of adjacent splats electrically contact each other, and thereby form an electrically conducting path through the target material layer. Preferably, the target material layer comprises at least some electrically conducting paths percolating through the target material layer. This may, for example, be the case when the concentration of M in the target material layer is sufficiently high, so that the chances of forming such percolating paths, by randomly projecting splats to form the target material layer by spraying, e.g. thermal spraying, becomes sufficiently high.

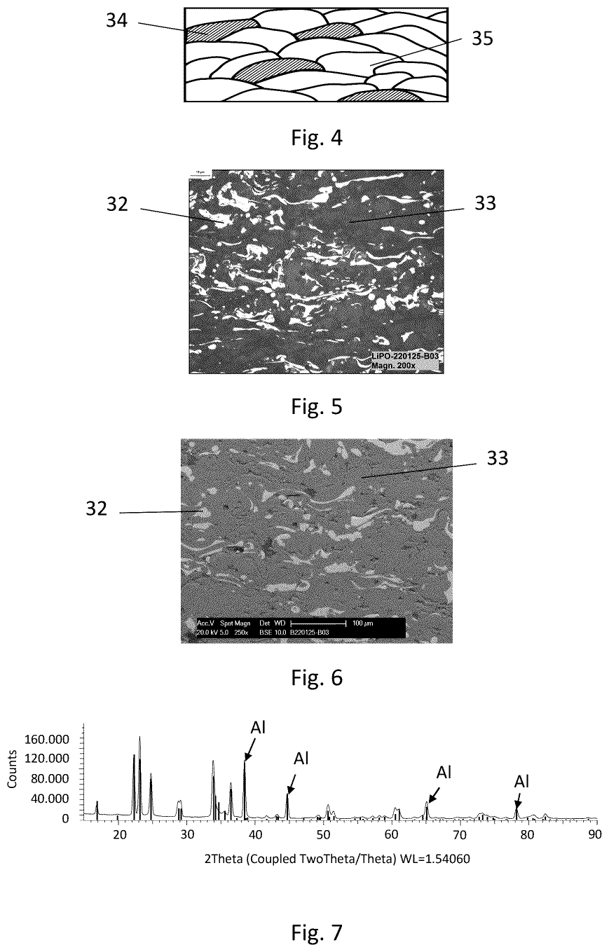

A second, different, example representing the sub-section of the target material layer 21 within the dashed lines in FIG. 2 is schematically shown enlarged, and in more detail, in FIG. 4. As can be observed, splats 34 of M, i.e., first regions 34 of M, are present in a matrix formed of splats 35 of LiₓPO_{y}, i.e., second regions 35 of LiₓPO_{y}. Although, in the embodiment illustrated, different splats 34 of M may be isolated from each other, electrical conduction between the different splats 34 of M, through the matrix formed of splats 35 of LiₓPO_{y}, may be possible due to, e.g., defects in the matrix, or along grain boundaries, e.g., boundaries of splats 34 and 35. Alternatively, in an embodiment not illustrated in the drawings, the concentration of M may be sufficiently high such that splats 34 formed of M electrically contact each other, thereby forming an electrically conducting path through the target material.

The invention is, however, not limited to either example, or may instead be a combination of both.

FIG. 5 is an optical microscopy image of part of a target material layer of a target in accordance with embodiments of the present invention. From ICP (Inductively Coupled Plasma) Spectroscopy, it was derived that the target material layer consists of Li_{2.97}PO_{4.3} with 13.5 wt. % of dopant M, which in this example is Al. The target material layer was formed by projecting a molten powder, by plasma spraying, onto a backing substrate. The powder, in non-molten form, that was used in this example, comprised particles formed of Al and particles formed of lithium phosphate. The picture is a result of a cross-section of the target material layer having a lamellar structure consisting of microscopic splats. The splats comprise first regions 32 formed of Al, and second regions 33 formed of LiₓPO_{y}. These separate regions can also be observed in FIG. 6, which is a scanning electronic microscope image in back scattering mode with Z contrast of part of the target material layer of the target of FIG. 5.

Reference is made to FIG. 7, which is an X-ray diffraction (XRD) spectrum of the same target material layer as shown in FIG. 5 and FIG. 6, i.e., comprising Al as dopant M. In the spectrum, the four peaks attributed to Al are indicated. Other peaks are attributed to LiₓPO_{y}. The XRD spectrum indicates a single orthorombic lithium phosphate phase, which is also observed in pure Li₃PO₄ reference coatings (which pure reference coatings are not in accordance with embodiments of the present invention). As such, also this XRD spectrum of a target material layer in accordance with embodiments of the present invention, clearly indicates that no mixing occurs between Al and LiₓPO_{y}. Furthermore, the spectrum shows that aluminium is present in metallic form embedded in the LiₓPO_{y} matrix, and as such may be selected for providing electrical conductivity to the target material layer.

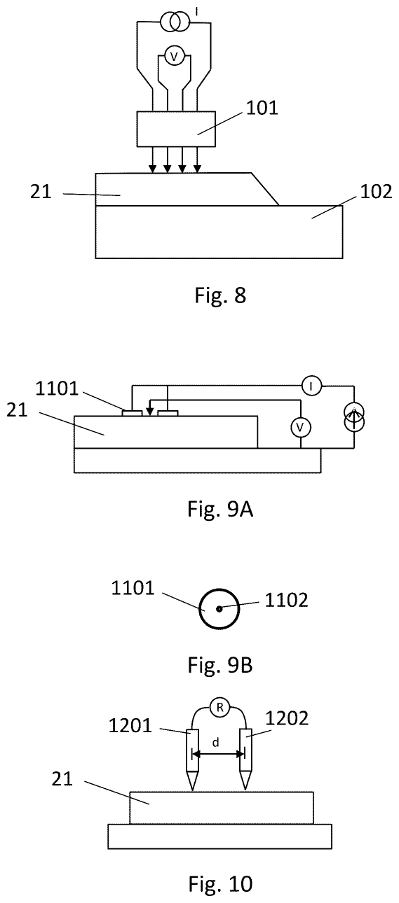

FIG. 8 to FIG. 11 are schematic representations of exemplary setups that may be used for measuring the electrical resistivity of a target material layer 21 of a target in accordance with embodiments of the present invention. In each setup, the target material layer 21 is placed on a carrier backing 102, and different probes (depending on the setup) are applied to the surface of the target material layer 21.

A 4-point method of measuring electrical resistivity, for which a setup is shown in FIG. 8, is based on a 4 point probe 101 including a voltage source providing a voltage V and a current source providing a current I. The resistivity is obtained from the equation:

$$ρ = \frac{V}{I} \frac{π t}{ln ( \frac{sinh ( t / s )}{sinh ( t / 2 s} )}$$

where the parameters t and s are respectively the thickness of the target and the space between contacts. This equation can be simplified to:

$$ρ = 2 * π * s * V / I$$

The 4-point method is the preferred method for determining the resistivity of the target. Resistivities for targets in accordance with embodiments of the present invention ranging from 0.001 Ω·cm to 0.5 Ω·cm have been measured, wherein the resistivity is typically about 0.01 Ω·cm.

A 3-point method of measuring resistivity, for which a setup is illustrated in FIG. 9A, is based on sending a current through a predetermined area (circular area provided by a circular plate 1101, in the present example, of which the top view is shown in FIG. 9B), and then measuring the current and voltage of the target material layer 21, in the case illustrated measuring through the center 1102 of the plate 1101. The resistivity is obtained from the equation:

$$V / I = R = ρ \cdot D / S$$

where D is the thickness (cm) of the target material layer 21 and S the contact surface (cm²) between the circular plate(s) 1101 and the target material layer 21.

A 2-point method, for which a set-up is shown in FIG. 10, simply measures the resistance between two probes 1201, 1202 (e.g., probes with steel point or Ni plated brass probes), at a predetermined distance d.

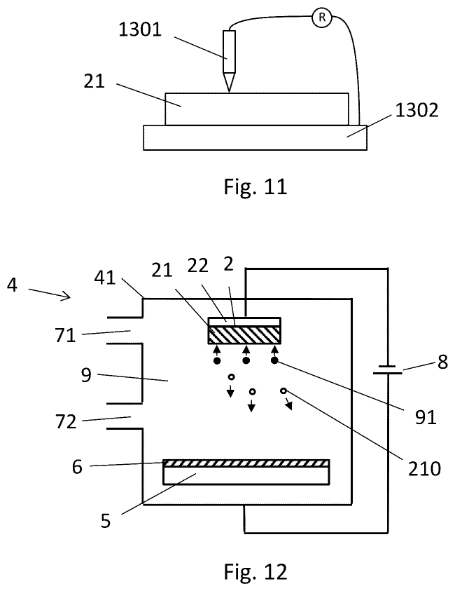

A single point method, for which a set-up is illustrated in FIG. 11, is based on measuring the resistance between an electrode 1301 in contact with a first surface of the target material layer 21 and the carrier backing that is used as an electrode 1302.

For the 2-point and single point method, which are experimentally relatively simple to perform, typically, modelling is required so as to determine the resistivity from the measured resistance. Suitable models are known to the person skilled in the art.

Preferably, for each of the methods mentioned above, a contact surface area between each probe or electrode for measuring the electrical resistance, and the target material layer 21, is equal to at least 1 time, such as at least 10 times, preferably at least 100 times, more preferably at least 1000 times, the average diameter of a splat within the target material layer 21. Thereby, a plurality of regions of dopant M may be electrically contacted by the probe or electrode, so that the electrical resistivity may be determined accurately. As such, any of the above setups may be used to verify that the electrical resistivity of the target material layer 21 is at most 1000 Ω·cm at room temperature.

In a third aspect, the present invention relates to a method for depositing a layer on a substrate. The method comprises obtaining a target in accordance with embodiments of the first aspect of the present invention, and sputtering, in a reactive gas atmosphere at least comprising N, target material from the target material layer of the target onto the substrate. Said sputtering is performed such that M reacts with a component of the reactive gas atmosphere, thereby forming an electrically insulating material, so as to form the deposited layer comprising LiPON and said electrically insulating material.

Reference is made to FIG. 12, which is a schematic representation of a sputtering setup 4, which may be used in a method for depositing a layer, wherein the method is in accordance with embodiments of the third aspect of the present invention. A sputtering chamber 41 of the sputtering setup 4 comprises a target 2 for sputtering that is in accordance with embodiments of the first aspect of the present invention. In this example, the target 2 is a planar target, but it may instead be a cylindrical target such as described above. The sputtering chamber 41 further comprises a substrate 5. The substrate 5 may be any suitable type of substrate. For example, the substrate 5 may be a silicon substrate or a glass substrate.

The target 2 is electrically coupled to a power source 8, such that the target 2 functions as a cathode. The power source 8 is for generating a negative potential on the target 2. The power source 8 preferably is a DC power source or an AC power source, wherein the DC power source may be used in a pulsed mode or in a non-pulsed mode. In the example illustrated, the power source 8 is configured for DC operation. While using a pulsed DC-mode or dual target set-up in AC-mode (not shown) said electric field may be generated at a frequency of at most 250 kHz. The target 2, or its backing substrate 22, may optionally be coupled to a cooling system (not illustrated). The present invention may also provide a free standing target, without a backing substrate 22.

A gas inlet 71 to the sputtering chamber 41 allows introducing gas into the sputtering chamber 41 so as to form a sputtering atmosphere 9 inside the sputtering chamber 41. A gas outlet 72 may be connected to a vacuum pump, for removing gas out of the sputtering chamber 41. The gas that is introduced into the sputtering chamber 41, in accordance with embodiments of the present invention, comprises nitrogen (N₂) and possibly an inert gas, typically argon. Optionally, the gas further comprises oxygen (O₂). The reactive sputtering atmosphere comprises nitrogen (N₂). The pressure of the atmosphere in the sputtering chamber may typically be from 0.1 Pa to 10 Pa.

In such a low pressure environment, whenever power is applied by the power source, an abnormal glow discharge may be generated. The abnormal glow discharge may ionize the gas to form ionized atoms or molecules 91, e.g., Ar⁺, N₂⁺ or O₂⁺ near the target 21 which may, as a result of the applied field, be accelerated towards and bombard the target material layer 21. By the bombardment by the ionized atoms or molecules 91, target material particles 210 are sputtered from the target material layer 21 of the target 2, towards the substrate 5, so as to form a deposited layer 6 over the substrate 5.

Due to a reaction between LiₓPO_{y} from the target material layer 21 and the nitrogen of the reactive sputtering atmosphere 9, LiPON may be formed. Furthermore, due to a reaction between the dopant M from the target material layer 21 and a component of the reactive sputtering atmosphere, which may be nitrogen and/or, when present, oxygen, an electrically insulating material may be formed, e.g., an M-nitride and/or an M-oxide. Without being bound by theory, the reaction between LiₓPO_{y} and nitrogen, and the rection between the conductive dopant M and the reactive sputtering gas, e.g., oxygen and/or nitrogen, may occur either when LiₓPO_{y} and M are still present in the target 2, or when LiₓPO_{y} and M are deposited onto the substrate to form the deposited layer 6. In the pressure ranges typically used (0.1 Pa to 10 Pa), said reactions may take place on any surface that is exposed to target material particles 210. The deposited layer 6 that is, as such, formed on the substrate 5, comprises a mixture of LiPON and the electrically insulating material, and substantially does not comprise an electrically conductive component (i.e., substantially all deposited M has reacted to form an insulating material), and is therefore electrically insulating.

It is to be understood that although preferred embodiments, specific constructions and configurations, as well as materials, have been discussed herein for devices according to the present invention, various changes or modifications in form and detail may be made without departing from the scope of this invention. For example, any formulas given above are merely representative of procedures that may be used. Functionality may be added or deleted from the block diagrams and operations may be interchanged among functional blocks. Steps may be added or deleted to methods described within the scope of the present invention.

1.-15. (canceled)

16. A target comprising a target material layer mainly comprising M-doped LixPOy,
wherein x is from 2.5 to 3.5 and wherein y is from 2.5 to 4.5,
wherein M represents up to 40 wt. % of the target material layer, and
wherein M comprises at least one chemical element from groups 13 to 15 of the periodic table,
wherein M is selected for providing electrical conductivity to the target material layer such that an electrical resistivity of the target material layer is at most 1000 Ω·cm at room temperature, and
wherein the target material layer has a lamellar structure consisting of microscopic splats of material.

17. The target according to claim 16, wherein M represents from 5 to 25 wt. % of the total target material layer.

18. The target according to claim 16, wherein M comprises a metal and/or a metalloid element.

19. The target according to claim 18, wherein M comprises at least one chemical element selected from silicon, boron, aluminium, and gallium.

20. The target according to claim 16, wherein M comprises at least one chemical element from group 13 of the periodic table.

21. The target according to claim 16, wherein the target material layer comprises at least 80 wt. % of M-doped LixPOy.

22. The target according to claim 16, wherein the target is a cylindrical target.

23. The target according to claim 16, wherein the microscopic splats comprise first regions of M and second regions of LixPOy.

24. The target according to claim 16, wherein the target material layer has a porosity below 20%.

25. A method for forming a target for sputtering, the method comprising:
providing powder comprising particles of lithium phosphate and particles of M and/or comprising particles of M-doped lithium phosphate,
wherein M comprises at least one chemical element from groups 13 to 15 of the periodic table,
providing a backing substrate, and
spraying splats, formed upon impact of the powder, onto the backing substrate, so as to form a target material layer comprising M-doped LixPOy,
wherein x is from 2.5 to 3.5 and wherein y is from 2.5 to 4.5, and
wherein M represents up to 40 wt. % of the total target material layer and is selected for providing electrical conductivity to the target material layer such that an electrical resistivity of the target material layer is at most 1000 Ω·cm at room temperature.

26. A method for depositing a layer on a substrate, the method comprising:
obtaining a target in accordance with claim 16, and
sputtering, in a reactive gas atmosphere at least comprising N2, target material from the target material layer of the target onto the substrate,
wherein said sputtering is performed such that M reacts with a component of the reactive gas atmosphere, thereby forming an electrically insulating material, so as to form the deposited layer comprising LiPON and said electrically insulating material.

27. The method according to claim 26, wherein said sputtering is DC sputtering or AC sputtering at a frequency of at most 250 kHz.

28. The method according to claim 26, wherein said sputtering is performed such that M reacts with nitrogen and/or oxygen during sputtering to form a nitride, oxide or oxynitride of M.

29. The method according to claim 26, wherein said sputtering is performed so as to form a deposited layer having an electrical resistivity that is at least 107 Ω·cm.

30. Use of a target according to claim 16 in a stable plasma sputtering process powered by a mid-frequency sputtering process or a DC sputtering process.
